(19) United States
(12) Patent Application Publication
(10) Pub. No.: US 2007/0243714 A1
(43) Pub. Date: Oct. 18, 2007

(54) Method of controlling silicon-containing polymer build up during etching by using a periodic cleaning step

(75) Inventors: Taeho Shin, San Jose, CA (US); Jingbao Liu, Sunnyvale, CA (US); Ajey M. Joshi, San Jose, CA (US); Jong Mun Kim, San Jose, CA (US); Wei-Te Wu, Cupertino, CA (US)

Correspondence Address: SHIRLEY L. CHURCH, ESQ., P.O. BOX 81146, SAN DIEGO, CA, 92138, US

(73) Assignee: Applied Materials, Inc.

(21) Appl. No.: 11/406,000

(22) Filed: Apr. 18, 2006

(51) Int. Cl. H01L 21/461; C03C 15/00

(52) U.S. Cl. 438/706; 438/710; 438/717; 438/725; 216/89

(57) ABSTRACT

A method of removing a silicon-containing hard polymeric material from an opening leading to a recessed feature during the plasma etching of said recessed feature into a carbon-containing layer in a semiconductor substrate. The method comprises the intermittent use of a cleaning step within a continuous etching process, where at least one fluorine-containing cleaning agent species is added to already present etchant species of said continuous etching process for a limited time period, wherein the length of time of each cleaning step ranges from about 5% to about 100% of the time length of an etch step which either precedes or follows said cleaning step.

### BACKGROUND OF THE INVENTION

1. Field of the Invention

The present invention pertains to a method of plasma etching recessed structures such as a high aspect ratio capacitor well, a contact via, or a trench into a semiconductor structure which includes a silicon-containing layer.

2. Brief Description of the Background Art

This section describes background subject matter related to the invention, with the purpose of aiding one skilled in the art to better understand the disclosure of the invention. There is no intention, either express or implied, that the background art discussed in this section legally constitutes prior art.

Deep recessed structure etching is one of the principal technologies currently being used to fabricate capacitive storage nodes, contact vias and trench features into semiconductor structures. Strict control of the etch profile is needed to provide deeply etched features having the required critical dimensions. Due to the current size of device structures, the patterns to be formed in a photoresist by imaging techniques require a limitation on the thickness of the photoresist layer which is being patterned. To meet critical feature dimensions, the thickness of the photoresist which can be imaged may be in the range of about 250 nm or less. To provide sufficient time for deep etching of an underlying substrate through a patterned mask, it is necessary to use a hard masking material under the photoresist, and to use the patterned photoresist to pattern the hard mask. During plasma deep etching of a trench, contact opening, capacitive storage node, or other opening into a substrate underlying the photoresist mask and the hard mask, a carbon-containing gas may be used as a part of the etchant plasma source gases. The carbon-containing gas contributes polymer forming materials which plate out on the upper surface of the photoresist mask or the hard mask, whichever is exposed. This plating out of polymer protects the patterned photoresist or the hard mask during the etching process, so that it lasts longer and enables deeper etching. However, due to a decrease in the size of the critical feature being etched to about 100 nm or smaller, the plating out of protective polymer has begun to plug up the openings in the patterned photoresist or hard mask.

Frequently silicon is present in at least a portion of the structure which is being etched. The silicon may be present in a hard masking material, such as silicon oxide, silicon nitride, silicon oxynitride, or silicon carbide, by way of example. Since the etching process is generally a dry plasma etch process, reactive species which include silicon are typically formed during the etching process. These reactive species become part of a hard polymeric residue which forms on surfaces in the area of the etch process. The hard polymeric residues interfere with the etching process, affecting the final etched structure top critical dimension (CD) and CD bias uniformity, by way of example. In the worst case, if the hard polymeric residue build up is sufficient in quantity, the openings to smaller critical dimension features which are to be etched may completely plug up so that etching is stopped. Use of increased power to drive the etch plasma, for purposes of increasing etch rate, typically leads to an increase in the amount of hard, silicon-containing polymeric residues which are formed. Thus, concerns about formation of the residues affects the ability to increase the etch rate during etching of a deep recessed structure.

In U.S. Pat. No. 5,281,302, issued Jan. 25, 1994, Gabric et al. describe a method for cleaning parasitic layers of silicon oxide and silicon nitride from a reaction chamber. The method includes introducing a gaseous etchant mixture into the reaction chamber, where the etchant mixture main constituent is at least one fluoridated carbon, to this etchant mixture an ozone/oxygen mixture (O₃/O₂) is added, and then the mixture is ignited to form a plasma. (Abstract) The pressure in the processing chamber ranges from about 100 Pa to 5,000 Pa (Col. 3, line 49). In a related method for removing parasitic layers in a reaction chamber, the etchant mixture is (O₃/O₂) which is excited to form a plasma (claim 5).

U.S. Pat. No. 5,968,278, issued on Oct. 19, 1999 to Young et al. describes an etching procedure for High Aspect Ratio (HAR) openings into a semiconductor substrate, where a three sequence etching process is employed to improve the HAR opening profile. (Abstract) The etch process involves three steps: a first, Main Etch 1, step in which two fluorocarbon gases and carbon monoxide (CO) are used as plasma precursor gases; a second, Main Etch 2, step in which two fluorocarbon gases, CH₂, CO, O₂ and argon are used as plasma precursor gases; and an “over-etch” step in which two fluorocarbon gases and O₂ are used as plasma precursor gases.

In Taiwanese Patent TW388930B, published May 1, 2000, Huang Yuan Chang describes a method of improving the etch back uniformity of a silicon-on-glass (SOG) layer by removing an etch back resistant polymer which builds up on the SOG layer during the etch back process. A first insulation layer and a SOG layer are formed on a substrate. The SOG layer is partially etched back in a fluorocarbon-containing plasma, during which a polymer residue forms on the SOG layer surface. The SOG layer is then treated in situ with an oxygen containing plasma to remove any of the etch resistant polymer residue on the SOG layer surface. The etching of SOG layer followed by removal of polymer residue may be repeated until the SOG layer is etched back to the desired thickness.

In U.S. Pat. No. 6,323,121, issued Nov. 27, 2001, Liu et al. describe a method for cleaning freshly etched dual damascene via openings and preparing them for copper film, allegedly without damage or contamination to exposed organic or other porous low-k insulative layers. The method employs an in-situ three-step treatment comprising a first step of exposing the electrically biased substrate wafer to an O₂N₂ ashing plasma to remove photoresist and polymers, a second step plasma treatment step with an H₂/N₂ plasma immediately following the first step, to remove silicon nitride etch stop layers, and a final step of treating the wafer with H₂/N₂ to remove copper polymer deposits formed during nitride removal. The H₂/N₂ plasma is said to be capable of removing the difficult polymer residues which would otherwise be removable only by wet stripping procedures. The H₂/N₂ plasma is said to not be harmful to exposed porous low-k dielectric layers as well as copper metallurgy. (Abstract)

Tumen Allen III, in U.S. Pat. No. 6,533,953, issued Mar. 18, 2003, describes a etching a material supported on a surface of a substrate in a reaction chamber, and then cleaning a component comprising species that were present in the material from the sidewall of a reaction chamber in which the substrate was etched. The reaction chamber is cleaned while the substrate is present in the chamber, supposedly without further removing the material from or other materials from the substrate surface. (Abstract) claim 12 recites that the cleaning is obtained by exposing the reaction chamber sidewall to a plasma comprising a combination of oxygen (O₂) atoms and a member of a group consisting of SF₆, chlorine atoms, and NF₃. The plasma may include, for example, SF₆/O₂, Cl₂/O₂, or NF₃/O₂. (Col. 5, lines 29-30)

U.S. Pat. No. 6,797,627 to Shih et al, issued Sep. 28, 2004, describes a method for the removal of polymer, possibly mixed with copper oxide residue, from exposed surfaces after an etch stop layer has been removed from a semiconductor structure. The exposed surfaces are treated with a first plasma etch followed by a DI water rinse, after which a second plasma etch of the exposed surfaces is performed. By selecting the chemistry and the conditions for the first and the second plasma etch, polymer residues and formed copper oxide residues are removed from the exposed surfaces. (Abstract)

Igarashi et al, in U.S. Published Patent Application US2005/0269294 A1, published Dec. 8, 2005, describe an etching method which includes multiple etchings which are sequentially performed in a single processing vessel on a laminated film having a plurality of layers formed on a substrate to be processed, without unloading the substrate to be processed from the processing vessel.

Between the etchings, a cleaning process is performed, for removing deposits from the processing vessel. A plasma generated from a source gas containing O₂ may be used, and preferably the source gas is a mixture of O₂ and N₂ gas. Further, the cleaning processing is performed under conditions of 50 to about 200 mTorr. (Abstract) The method makes use of three etching gas supply units, a first etching gas supply unit which furnishes a mixture of C₅F₈/Ar/O₂; a second etching gas supply unit which furnishes a mixture of CH₂F₂/Ar/O₂; and a cleaning gas supply unit which furnishes a mixture of N₂/O₂. All gas supply mixtures are connected to valves and mass flow controllers. (Page 2, Paragraph [0028])

Other fluorocarbon gases than those particularly described above are also mentioned in the published reference. This published application also teaches at Page 3, Paragraph [0040], that when the cleaning procedure is used, it is preferable that the gap between the susceptor and the upper electrode be set considerably larger than the gap during etching, in order to avoid any effects on the wafer (substrate). At Page 3, Paragraph [0046] continuing through Page 4, Paragraph [0048], the published application teaches that after a first etching of the substrate to remove a silicon oxide film, deposits remain on the inner wall surface of the etching chamber, and that if a second etching processing is to be performed in the etching chamber, it is helpful to remove the deposits from the chamber prior to performing the second etching process. Further, that after the cleaning procedure, a second etching process is performed in which a silicon nitride film is etched, using a photosensitive resist film and a silicon oxide film as a mask.

Numerous processing techniques have been proposed to solve the challenges related to etching of deep pathways into a semiconductor substrate. Some of these techniques are used to control the shape (sidewall taper, for example) of the etched profile, while simultaneously providing a smooth surface on the etched sidewall and the desired critical dimensions at various locations along the pathway. Whenever the etching process produces byproducts which become residue on surfaces of the etched pathway or on surfaces near the entryway to the pathway which is being etched, this creates problems by disturbing the flow of etchant materials at the entry or within the pathway which is being etched. The problems in etchant flow are illustrated by distortions in the pathway. For example, when hard polymeric residue (such as that generated by silicon-containing compounds) is present near the upper surface of the pathway into which the etchant materials must enter to continue the etching process, the etched profile tends to be more tapered toward the bottom and the desired dimension of the etched opening/pathway at its base (the bottom CD) may not be obtained. In addition, the etched profile may exhibit bowed sidewalls. When the etched opening is an electrical contact which must be filled with a conductive material, a bowed sidewall may prevent proper filling of the contact.

### SUMMARY OF THE INVENTION

We have developed a method of plasma etching deeply recessed features such as, but not limited to, deep trenches, contact, vias, or wells used for embedded DRAM circuits, for example and not by way of limitation, where the trenches or holes have an aspect ratio of about 15:1 or greater, typically the aspect ratio ranges from about 18:1 to 20:1. The aspect ratio refers to the ratio of the depth of the trench:width at the top of the trench, or the ratio of the depth of the opening into the substrate: equivalent diameter at the top of an opening, by way of example. Recently, the depth of openings being etched into a dielectric layer may be as much as 2.5 microns or more. Despite the depth of etching into the dielectric layer, and the high aspect ratio, the current etching method generates smooth sidewalls, exhibiting minimal to no striations when viewed using a scanning electron microscope. The sidewall taper angle, relative to a horizontal plane parallel to the face of the substrate, typically ranges from about 85° to about 90°, except in instances where the design specifically calls for a taper (such as when a contact is to land on a surface area which is smaller than the opening at the top of the contact hole). Frequently the etching is carried out within a carbon-containing substrate such as a low k dielectric. The method provides control over the amount of carbon-containing material which builds up on etched surfaces, so it is possible to control the shape of the etched surfaces as the etching progresses in such a substrate. The amount of carbon-containing material which deposits on surfaces during etching depends on the composition of the plasma source gases and the general process conditions used during the basic etching process, in combination with the plasma source gases and general process conditions used during a periodic cleaning process. Often, the basic etching process and the cleaning process are two steps which are repeated to provide a cycle and a given number of cycles are carried out during the deep etching process. The length of time during which the cleaning step is carried out is frequently, but need not be, short compared with the length of time of the basic etch step. The time length of the cleaning step may range from about 5% to about 100% of the basic etch step. However, typically the time length of the cleaning step ranges from about 5% to about 10% of the time length of a basic etch step which precedes or follows the cleaning step. The higher the carbon content in the depositing carbon-containing residue, the more difficult it is to remove the carbon-containing residue, and the longer the cleaning step time relative to the basic etch step.

The number of plasma cleaning steps carried out during a plasma etch of a deeply recessed feature depends on the depth of the feature to be etched and the rate at which hard silicon-containing and carbon-containing residue materials accumulate on surrounding surfaces during plasma etching of the feature. One skilled in the art, after reading the disclosure herein will be able to optimize the number of cleaning steps carried out during a given basic etch process to provide an acceptable control over the etched feature dimensions (so that they meet a given product specification) while maintaining an acceptable cost of production.

The overall composition of the plasma species in a plasma cleaning step is different from the overall composition of the plasma species used in a basic etch step which precedes or follows a plasma cleaning step during the etching of a feature.

The plasma etchant species in a basic etch step preceding a plasma cleaning step may be the same as or different from the plasma etchant species which are present in a basic etch step following a plasma cleaning step. However, typically the plasma species used during the basic etch steps, whether preceding or following the plasma cleaning step, are essentially the same for etching a substrate of essentially constant composition. The plasma species used in the plasma cleaning steps are also typically essentially the same throughout the plasma etching of the feature into a substrate of constant composition. However, in instances where the problem of hard polymer residue plating out at the openings on the upper surface of substrate decreases with time during the deep feature etch, either the length of time of the plasma cleaning step or the composition of the of the plasma species in the plasma cleaning step may be adjusted, as the etching of the feature into the semiconductor substrate progresses.

While the plasma species used during the cleaning step may be completely different from the plasma species in the basic etch step preceding and/or following the cleaning step, it is more typical for the cleaning step plasma species to include additional species in combination with the plasma species which are present in an etch step preceding and/or following the cleaning step. The plasma species in the plasma cleaning step may be created by the addition of specialized source gases to the plasma source gases which are used during the basic plasma etch steps. The additional, specialized plasma source gases generate species which enable the removal of hard polymeric residues from the etched semiconductor surfaces and adjacent surfaces. To provide ease of control, the general process conditions and etch plasma source gases used during basic etch of the feature may be maintained throughout the entire etching of the feature, including during the cleaning steps, with the specialized plasma source gases added intermittently during the cleaning steps only.

The plasma species used in the cleaning step are often created by adding a combination of oxygen (O₂) and a CₓF_{y} gas, where the ratio of x:y ranges from 1:4 to about 1:1. Carbon tetrafluoride (CF₄) works particularly well in combination with oxygen, when added as source gases for the plasma during an intermittent cleaning step which is carried out during the basic etching step. The typical volumetric ratio of oxygen to carbon tetrafluoride in the plasma source gas added during an intermittent cleaning step ranges from about 1:20 to about 10:1.

While the embodiments described below are with reference to etching an amorphous carbon layer (which increases carbon content available for residue formation), which is particularly problematic to etch, the method of the invention may be used with a variety of different substrates. When silicon is present in the semiconductor structure which is to be etched, (for example when an organic or carbon-containing dielectric is etched, and there is a source of silicon in a layer adjacent to the dielectric, such as in the overlying hard mask) the method may be useful in preventing plugging of the entryway to openings in the carbon-containing dielectric during etching.

### BRIEF DESCRIPTION OF THE DRAWINGS

FIG. 1 is a cross-sectional schematic illustrating a typical semiconductor structure of the kind in which a deep etched feature is to be created.

FIG. 2 is a cross-sectional schematic of a 200 mm E-MAX CT+ etch chamber of the kind used to carry out the experimentation leading to the present invention.

FIG. 3A is a comparative example showing a schematic of a photomicrograph top view at the center of a substrate, where the openings being etched into an amorphous carbon layer 302 are completely filled by silicon-containing hard polymer build up 304 which occurred during the etching of a high aspect ratio capacitive node well.

FIG. 3B is a comparative example showing a photomicrograph side view of the etched amorphous, α-carbon, layer 302, with overlying silicon-containing hard polymer build-up 304, as shown in FIG. 3A.

FIG. 3C is a comparative example showing a photomicrograph top view at the edge of the substrate shown in FIG. 3A, where the openings in α-carbon layer 302 are still apparent, but the diameter of the openings has been reduced to less than 10% of the original pattern diameter opening exhibited in the overlying silicon oxynitride hard mask (not shown).

FIG. 3D is a comparative example showing a photomicrograph side view opening of the etched α-carbon substrate shown in FIG. 3C.

FIG. 4A shows a photomicrograph top view at the center of a semiconductor substrate where the holes in an α-carbon layer 402 of the substrate were etched using the method of the invention. Use of the method has enabled etching of the holes with minimal effect on the etch profile due to hard polymer build up.

FIG. 4B shows a photomicrograph side view of the etched α-carbon layer 404 (and adjacent layers) shown in FIG. 4A.

FIG. 4C shows a photomicrograph of a top view at the edge of the substrate shown in FIG. 4A, where holes were etched in the α-carbon layer 402.

FIG. 4D shows a photomicrograph side view of the of etched α-carbon layer 402 shown in FIG. 4C.

### DETAILED DESCRIPTION OF EXEMPLARY EMBODIMENTS

As a preface to the detailed description, it should be noted that, as used in this specification and the appended claims, the singular forms “a”, “an”, and “the” include plural referents, unless the context clearly dictates otherwise.

When the word “about” is used herein, this is an indication that the precision of the number provided is within ±10%.

We have developed a method of plasma etching deeply recessed features such as, but not limited to, deep trenches, contact holes, and wells used for embedded DRAM circuits, for examples, where the trenches or holes have an aspect ratio of about 15:1 or greater. An aspect ratio is the ratio of the depth of the trench to the width of the trench at its upper surface, or the ratio of the depth of the hole to the diameter of the hole at the entry to the hole. For purposes of discussion herein, the critical dimension of a hole or well is the opening equivalent diameter at the top of the hole or well. The aspect ratio is important, because typically, as the aspect ratio increases, the difficulty in moving the etch front forward at a desired, controlled dimension becomes more difficult. The method of the invention generates smooth sidewalls on the etched trench or holes, where no striations are observed when looking at the etched surface of the trench or hole through a SEM. The method also enables control over the shape of the sidewalls as they are etched. Typically a sidewall taper angle, relative to a horizontal plane parallel to the face of the substrate, ranges from about 85° to about 90°. However, in some instances, such as with a contact via where the landing area beneath the upper surface of the contact opening is particularly small, it may be desirable to have a taper, and etch conditions may be controlled to produce a taper which is in the range down to about 70°.

The method of the invention employs the intermittent use of a plasma cleaning step for removal of etch residue as it is produced, during the plasma etching of the deeply recessed features, so that the plasma entryway area (opening) to the feature being etched does not become plugged or impeded in a manner which affects the profile etched beneath the entryway area. The time period of a plasma cleaning step is short relative to the length of a plasma etch step which either precedes or follows the plasma cleaning step. Typically the time length of the plasma cleaning step ranges from about 5% to about 10% of the time length of an etch step which either precedes or follows the cleaning step. The number of plasma cleaning steps carried out during a plasma etch of a deeply recessed feature depends on the depth of the feature to be etched and the rate at which hard polymeric residue accumulates on surrounding surfaces during plasma etching of the feature.

Hard polymeric residue refers to silicon-containing/carbon-containing residue. The higher the silicon content and the higher the carbon content in the residue, the more difficult it is to remove the silicon-containing/carbon-containing residue. One skilled in the art, after reading the disclosure herein will be able to optimize the number of cleaning steps carried out during a given etch process to provide acceptable control over the etched feature dimensions (so that they meet a given product specification) while maintaining an acceptable cost of production.

The overall composition of the plasma species in a plasma cleaning step is different from the overall composition of the plasma species used in a plasma etch step which precedes or follows the plasma cleaning step during the etching of a feature. The etching of a feature refers to the etching of an opening through, a hole into, or a pathway into a substrate having an essentially constant composition. The plasma etchant species in a plasma etch step preceding a plasma cleaning step may be the same as or different from the plasma etchant species which are present in a plasma etch step following a plasma cleaning step. However, typically the plasma species used during the plasma etch steps, whether preceding or following the plasma cleaning step, are essentially the same for etching a layer of constant composition. The plasma species used in the plasma cleaning steps are also typically essentially the same in each plasma cleaning step throughout the plasma etching of the feature. However, the composition of the plasma species in the plasma cleaning step may be adjusted as the etching of the feature into the semiconductor substrate progresses.

While the cleaning step plasma species may be completely different from the plasma species in the etch step preceding and/or following the cleaning step, it is more typical for the cleaning step plasma species to include the plasma species which are present in an etch step preceding and/or following the cleaning step. The plasma species in the plasma cleaning step may be created by the addition of a specialized source gas (or gases) to the plasma source gases which are used during the plasma etch steps. The additional, specialized plasma species enable the removal of silicon-containing hard polymeric residues from the semiconductor surfaces which are exposed to the cleaning step. To provide ease of control, but not as a necessity, the general process conditions and etch plasma species used during etch of the feature may be maintained throughout the entire etching of the feature, including during the cleaning steps, with the specialized plasma species added during the cleaning steps only.

The principal embodiment of the invention which is described herein is one of the most beneficial uses of the method of controlling silicon-containing hard polymer residue build up during etching of a semiconductor structure. As mentioned previously herein, a silicon-containing and carbon-containing hard polymer residue is more difficult to remove when the carbon content is higher. The principal embodiment illustrated pertains to the etching of a layer of α-carbon which underlies a hard masking layer which contains silicon (silicon oxynitride). As a result, the availability of carbon to participate in residue formation is increased. Silicon is present in the hard polymer residue because silicon is sputtered off the hard mask during etching of the underlying α-carbon layer.

The specialized plasma species which have proved to be particularly useful during a cleaning step, when the carbon content of the silicon-containing/carbon-containing hard polymer residue is particularly high, were created in the experimental examples which follow by adding a combination of oxygen (O₂) and carbon tetrafluoride (CF₄) gases to the plasma source gas during the cleaning step. The plasma source gas needs to contain fluorine to assist in the removal of the silicon-containing residue. The organic fluorides CₓF_{y} are preferred over SF₆ and NF₃, for example, because they do not introduce elements which would affect the main etch process. Typically, the ratio of x:y in the organic fluoride ranges from about 1:4 to about 1:1. In the instance where amorphous carbon is being etched, due to the availability of carbon from the etch process itself, it is advantageous to reduce the amount of carbon present in the organic fluoride, and CF₄ provides the fluorine species while minimizing the carbon content generated by the organic fluoride. Other examples of organic fluorides include C₂F₄, C₂F₆, C₃F₆, C₄F₆, C₄F₈, C₅F₈, and C₆F₆ by way of example and not by way of limitation.

Oxygen was added to the plasma source gas to assist in the removal of carbon from the silicon-containing/carbon-containing residue. The typical volumetric ratio of oxygen to carbon tetrafluoride in the plasma source gas added during the intermittent cleaning step ranges from about 1:20 to about 10:1.

A non-reactive diluent gas may be used in combination with the organic fluoride and oxygen source gases during a cleaning step. Examples of such non-reactive gases include helium, argon, and xenon, for example and not by way of limitation. Argon is preferred because it is readily available and because it can provide helpful physical bombardment activity during the plasma cleaning step. The amount of argon added to the cleaning step plasma source gas typically ranges from about 0% to about 500% by volume of the gases which are added during the cleaning step only for purposes of cleaning.

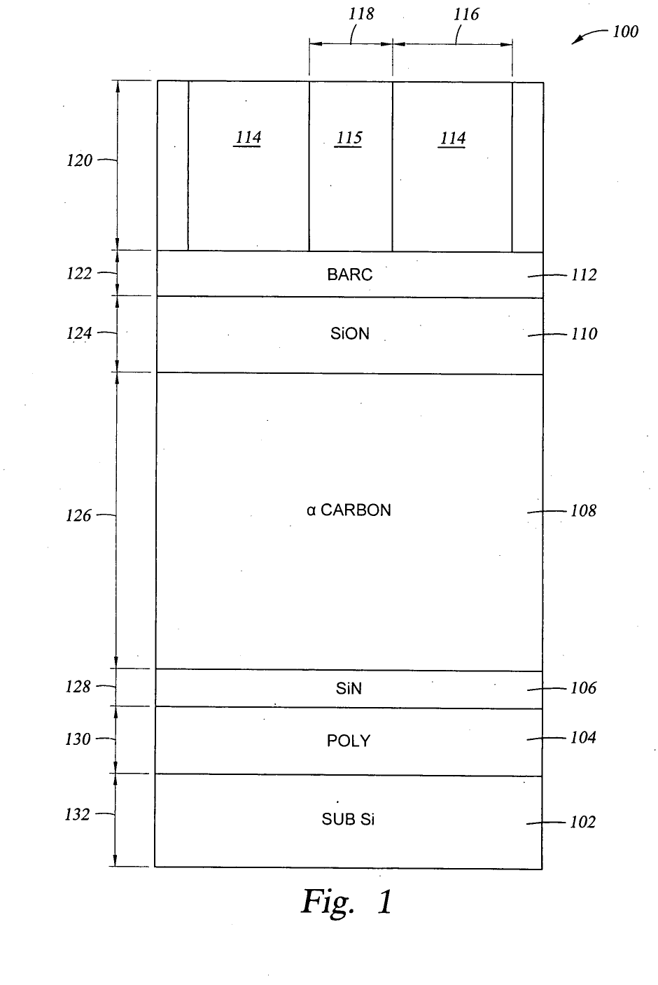

FIG. 1 shows a cross-sectional schematic illustrating one embodiment of a semiconductor structure 100 of the kind in which a deep etched feature may be created. This semiconductor structure is described in detail herein, because considerable experimentation was carried out using this structure. However, one skilled in the art will recognize that the method of the invention can be applied to other semiconductor structures as well. The semiconductor structure 100, which was a substrate used to form a high aspect ratio contact of an embedded DRAM circuit, includes from the bottom up: a single crystal substrate 102, which was typically about 0.8 mm thick, 132; a layer of polysilicon 104, which was typically about 150 nm thick, 130; a layer of silicon nitride 106, which was typically about 60 nm thick, 128; a layer of amorphous carbon 108, which was about 1,700 nm thick, 126; a layer of silicon oxynitride 110 which acts as a hard mask during etching of the amorphous carbon layer, where the silicon oxynitride layer was about 150 nm thick, 124; a layer of bottom anti-reflective coating (BARC) in the form or an organic BARC of the kind commonly used in the art when the photoresist is sensitive to 193 nm radiation, which is about 30 nm thick, 122; and a patterned resist layer of the kind known in the art which is sensitive to 193 nm radiation, 114, which was about 250 nm thick, 120. The patterned resist layer 114 includes openings 115 which were typically about 100 nm in diameter, 118. The thickness of the hard masking layer used during etching of the amorphous carbon layer 108 depends on the selectivity of the hard mask material relative to the amorphous carbon layer. The selectivity of the hard mask layer 110 should be at least 10:1 relative to the amorphous carbon layer, whereby the amorphous carbon layer 108 etches at least 10 times faster than the hardmask layer 110.

The experimental targets for etching of the high aspect ratio contact holes in the α-carbon layer 108 shown in FIG. 1 were: an opening 115 through the upper surface of the masking structure 114 having a diameter greater than 60 nm at the end of the etch process (i.e. the silicon-containing polymer deposition on the upper surface of the substrate during etching did not reduce the size of the opening to less than 60 nm); a bottom diameter at the base of the etched hole (Bottom CD) of greater than 80 nm; an etch profile angle (relative to the horizontal surface of the substrate above the hole) which is greater than 89 degrees (a nearly vertical etch profile); and, an etch rate which is greater than 500 nm per minute. Bowing of the etched hole profile should be less than 30 nm. When the etched hole profile is bowed, i.e. the wall is concave in shape when viewed from the interior of the hole, this forms a restriction within the hole profile which causes problems during subsequent filling of a contact hole with a conducive material.

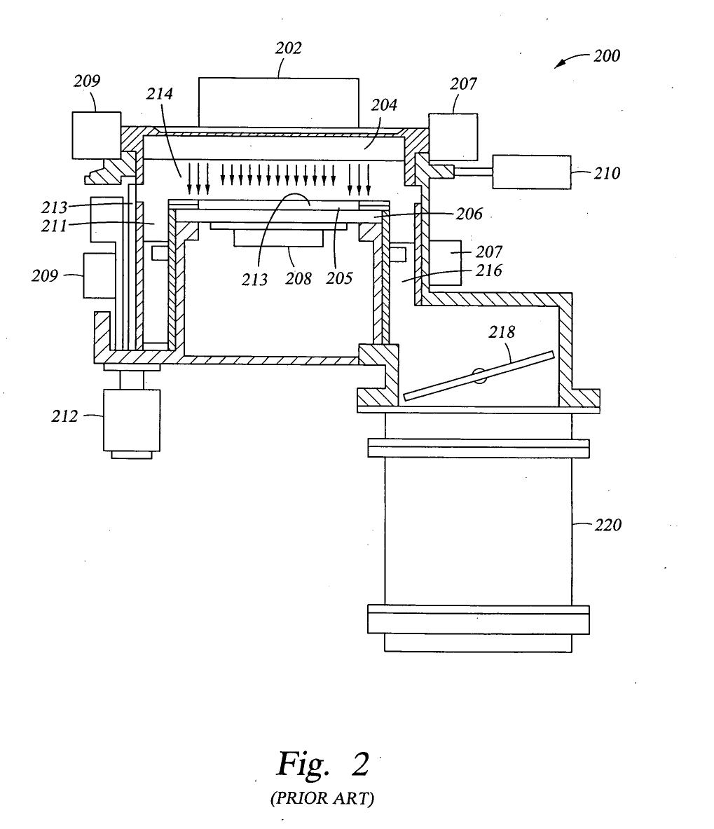

FIG. 2 is a cross-sectional schematic of a 200 mm E-MAX CT+™ etch chamber 200 of the kind used to carry out the experimentation leading to the present invention. This etch chamber is commercially available from Applied Materials, Inc., Santa Clara, Calif. The substrate 205 to be etched enters the processing area 214 through a slit valve which is created by using a magnet 212 to raise and lower a panel 213. The etch chamber 200 includes an RF plasma source power represented by anode electrode 204 and the matching impedance network 202. The anode electrode 204 works in combination with cathode electrode 208 and electrostatic chuck 206. The plasma flux is controlled using magnetic coils 207 and 209, with an additional symmetrical two magnetic coils not shown in the cross-sectional view. Typically the RF frequency used for the plasma source power is 60 MHz. The wattage applied during the experimentation described herein ranged from about 50 W to about 2,000 W for the 200 mm E-MAX CT+™ etch processing chamber. Typically, about 1500 W were applied for the amorphous carbon etching process, and about 1500 W were applied during a cleaning step as well. The substrate which is to be etched is commonly biased to attract etchant species toward the substrate. To bias the substrate, a high contact area RF power at 13.56 MHz is applied to cathode 208. The wattage applied during the experimentation described herein ranged from about 100 W to about 600 W for the 200 mm E-MAX CT+™ etch processing chamber. Typically about 600 W were used during an amorphous carbon etching process, and about 100 W were applied during a cleaning step.

Applied Materials, Inc. also offers for sale a 300 mm E-MAX™ etching processing chamber, and an Enabler™ etching process chamber which is capable of etching both 200 mm and 300 mm substrates. The 300 mm E-MAXT™ etch chamber uses a plasma source power of 60 MHz and a substrate bias power applied to cathode 208 which is a mixed frequency of 13.56 MHz and 2 MHz. The Enabler™ etching process chamber uses a plasma source power of 162 MHz, and a substrate bias power which is a mixed frequency of 13.56 MHz and 2 MHz. One skilled in the art can, with minimal experimentation, determine the wattage which needs to be applied for other apparatus to obtain the required etch rate and etch profile of the desired feature in view of the disclosure provided herein.

Plasma source gases from which plasma etchant species are to be created enters processing area 214 as a gas from a gas distributor 204. The plasma etchant species contact substrate 205 which is present on a substrate support pedestal which includes an electrostatic chuck (ESC) 206 and a cathode 208, which is used to electrically bias the substrate for purpose of attracting etchant species toward the substrate. Typically the substrate is biased at a voltage ranging from about 10 V to about 1200 V. A helium gas is commonly used to facilitate heat transfer between the substrate 205 and the electrostatic chuck 206. The helium gas enters through the electrostatic chuck 206 (gas transfer lines for this purpose are not shown on the schematic drawing). Various excess plasma source gases, heat transfer gases, and residual etchant species are removed from the etch chamber 200 through a conduit 216 which is under vacuum, and pass through a vacuum throttle valve 218 to vacuum pump 220.

The pressure in processing area 214 is controlled by a balance of the amount of plasma source gases entering through the gas distributor 204, the amount of helium heat transfer gas leakage into the processing area 214, (from the electrostatic chuck 206 fluid flow conduits (not shown)) and the amount of exiting gas and etchant species which are removed by the turbo vacuum pump 220. The amount of helium leakage is relatively small, a few sccms. The pressure in the processing area 214 is monitored by pressure manometer 210 which sends a signal to a controller used to control the vacuum throttle valve 218. Typically the pressure in the processing area 214 during the experimentation described herein was controlled to range between about 5 mTorr and about 40 mTorr. The overall processing gas flow through the processing area was controlled to range from about 60 sccm to about 185 sccm. Individual gases which make up the plasma source gases vary in flow rate and are described in detail in etch processing descriptions which follow. Etch chamber 200 pressure is controlled by a closed-loop pressure control system (not shown) which controls the various plasma source gases which are fed into the etch chamber 200 and the vacuum throttle valve 218. When the 300 mm size E-MAX™ processing chamber is used, the overall sccm of gases to the processing area 212 is approximately twice the flow described for the 200 mm size E-MAX™ processing chamber.

The substrate 205 temperature is controlled by cooling, using the helium heat transfer gas provided via the electrostatic chuck 206, as previously described. Commonly, substrate temperatures during the etch process range from about −20° C. to about 40° C. The temperature of the process chamber walls 211 which surround the substrate 205 are operated at a temperature which is warmer than the substrate surface 215. Heating/cooling channels (not shown) in chamber walls 211 are used to maintain the chamber walls at a temperature ranging from about 15° C. to about 50° C.

Although the etch process chamber 200 used to process the substrates described in the Examples presented herein was an inductively coupled etch chamber of the kind shown in schematic in FIG. 2, any of the etch processors available in the industry should be able to take advantage of the etch method described herein, with some adjustment to processing parameters which may be made after minimal experimentation.

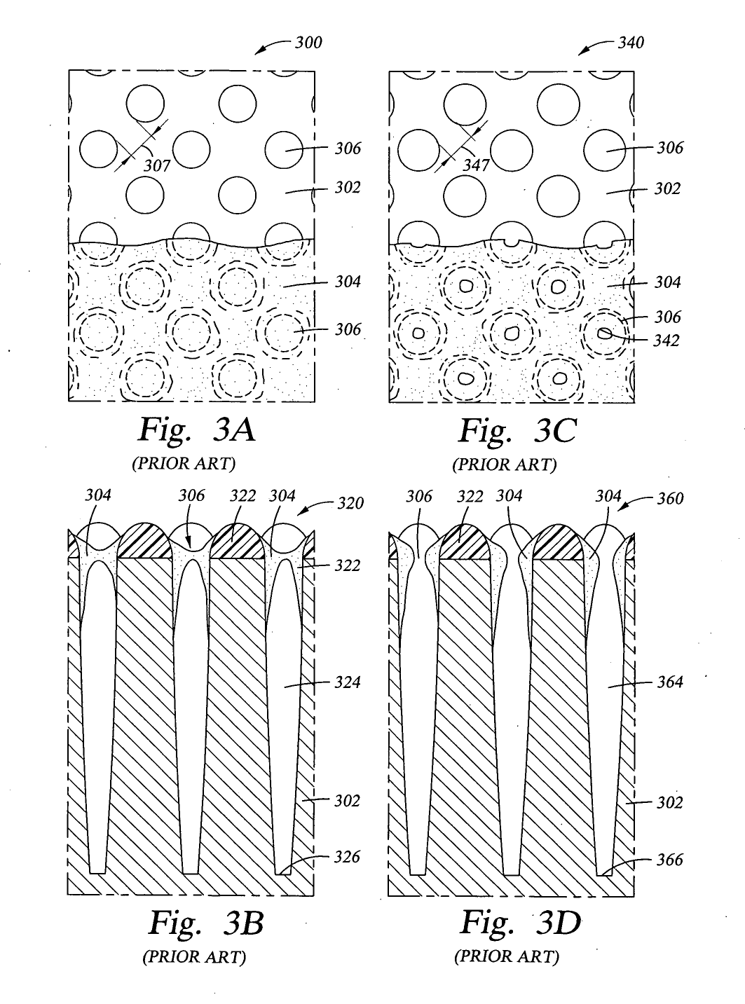

FIGS. 3A through 3D provide comparative examples of the etch problems encountered prior to the present invention. FIGS. 3A through 3D are photomicrographs which show the etch results obtained for etching the substrate shown in FIG. 1, when no hard polymer management program was used. The process conditions used during etch (referred to herein as Main Etch (ME) of the α-carbon layer 108 of the etch structure 100 shown in FIG. 1 were as follows: The plasma source gas contained H₂ at 120 sccm; N₂ at 60 sccm; and O₂ at 5 sccm. A flow ratio controller (not shown in FIG. 2) is used to control the plasma source gas flow rate at the center of the substrate 205 relative to the edge of the substrate. Typically, the ratio of plasma source gas flow, center: edge, ranges from about 26:1 to about 1:3.5. In this example, the flow ratio controller was operated with the ratio of gas flow for center: edge being 3:1. The plasma source power was 1600 W; the substrate bias power was 600 W; the pressure in the etch chamber was 15 mTorr; the substrate support pedestal was at about −15° C.; the etch chamber wall was at about 15° C.; and, the heat transfer helium back pressure on the backside of the wafer was about 12 Torr. The etch time was 5.4 minutes.

FIG. 3A is a photomicrograph top view 300 at the center of a substrate of the kind shown in FIG. 1, where the openings 306 are etched in the α-carbon layer 302. Silicon-containing hard polymer build-up 304 has accumulated toward the top of α-carbon layer 302, completely filling the openings which had originally been present at the top of each hole (well). The gradual filling of the wells distorted the shape of the wells as they were formed, as shown in FIG. 3B. The average critical dimension (diameter) of the openings 306 in the patterned α-carbon layer 302 was about 109 nm at the center of the substrate, with the “Bar CD”, the diagonal 307 between openings 306 being about 108 nm.

FIG. 3B is a photomicrograph side view 320 of the etched α-carbon layer 302 at the center of the test wafer as shown in FIG. 3A. Also shown in FIG. 3B is the silicon oxynitride hard mask 322 which was not shown in FIG. 3A, for purposes of better illustrating the silicon-containing hard polymer build-up 304. The silicon-containing hard polymer build-up 304 is shown filling the openings 306 which were at the top of the wells 324 in the α-carbon layer 302. α-carbon layer 302 in FIG. 3B, has been etched to provide wells 324 which have a depth of about 1.7 μm (1,700 nm). The diameter 326 at the base of well 324 is approximately 60 to 65 nm.

FIG. 3C is a photomicrograph top view 340 at the edge of a substrate of the kind shown in FIG. 1, where the openings 306 in the pattern-etched α-carbon layer 302 are partially filled by hard polymer build-up 304 which occurred during the etching of a high aspect ratio hole in an α-carbon layer 302 (shown unetched as 108 in FIG. 1). The average critical dimension (diameter) of the openings 306 in the pattern etched α-carbon layer 302 was about 140 nm at the edge of the substrate. The Bar CD, diagonal space, 347 between openings was about 70 nm.

FIG. 3D is a photomicrograph side view 320 of the etched α-carbon substrate at the edge of the test wafer as shown in FIG. 3C. The hard polymer build-up 304 is shown partially filling the openings 306 in the pattern-etched α-carbon layer 302. The α-carbon layer 302 has been etched to provide wells 364 which have a height of about 1.7 μm (1,700 nm). The diameter 366 at the base of well 361 is approximately 79 nm.

An analysis of the composition of the hard polymer build-up which was forming residue on the side walls and at the openings into the α-carbon layer indicated that elements present in the hard polymer build-up included silicon, carbon, oxygen and nitrogen. Further, careful review of photomicrographs indicated that the SiON hard mask shape was being eroded during etch by incoming ions. The silicon from the SiON hard mask appeared to be combining with carbon from the polymeric patterned photoresist mask (used to create the SiON hard mask) and carbon from the α-carbon layer as it was etched, to form hard-to-remove residue of polymer combined with compounds such as SiC or SiN, or SiON. Such hard-to-remove compounds were considered to require a fluorine-based chemistry to achieve removal. Fluorine-containing compounds such as SF₆, NF₃, and CₓF_{y} and combinations thereof are considered to be reliable fluorine-containing agents useful in the formation of plasmas for the removal of the hard polymer build-up. The CₓF_{y} compounds are considered to be better than the SF₆ and NF₃, because they do not introduce elements which affect the main etch chemistry used in etching of the α-carbon layer.

Several possible polymer removal etch schemes were evaluated on substrates after the completion of main etch of the α-carbon layer. Table I below shows the various etch parameters which were used in the effort to find a way of removing the silicon-containing hard polymer residue from the surface of the substrate.

TABLE ONE

| Test/ | | | | | | | | | | |
|---|---|---|---|---|---|---|---|---|---|---|
| Run | CF⁴ | O₂ | N₂ | Ws¹ | Wb² | | Ts⁴ | Tw⁵ | He⁶ | Time⁷ |
| No. | sccm | sccm | sccm | W | W | Pr³ | ° C. | ° C. | Torr | sec |
| 1 | 50 | 10 | — | 1600 | 300 | 15 | −15 | 15 | 12-12 | 30 |
| 2 | 50 | 10 | — | 1600 | 300 | 15 | −15 | 15 | 12-12 | 60 |
| 3 | 5 | 50 | — | 1600 | 300 | 15 | −15 | 15 | 12-12 | 30 |
| 4 | 0 | 50 | — | 1600 | 300 | 15 | −15 | 15 | 12-12 | 30 |
| 5 | 0 | 50 | — | 1600 | 600 | 15 | −15 | 15 | 12-12 | 30 |
| 6 | 5 | 50 | 10 | 1600 | 300 | 15 | −15 | 15 | 12-12 | 30 |

¹Plasma source power in Watts.
²Substrate bias power in Watts.
³Process chamber pressure in mTorr.
⁴Temperature of the substrate support platform.
⁵Temperature of the plasma chamber walls.
⁶The back pressure of helium heat transfer gas used on the backside of the wafer. There are two zones, center area and edge area which may be separately controlled. In this instance both zones were set at 12 Torr backpressure.
⁷Etch time in seconds.

Test 4, which employed only oxygen as the active plasma etchant in a silicon-containing hard polymer clean up was unsuccessful, leaving the openings to the SiON layer plugged with the silicon-containing hard polymer. Test 5, which increased the substrate bias power from 300 W to 600 W over the bias power used in Test 4, did not remove the silicon-containing hard polymer. Test 3, which employed a minor amount of CF₄ in the plasma source power did remove a portion of the silicon-containing hard polymer residue, but the openings in the patterned SiON layer remained plugged with the silicon-containing hard polymer after the cleaning. Test 6, which employed an addition of nitrogen with the minor amount of CF₄ and the constant amount of oxygen in the plasma source gas in the plasma cleaning etch appeared to remove slightly less of the silicon-containing hard polymer than that which was removed in Test 3. While Test 1, which employed an amount of CF₄ relative to oxygen which was 5:1, did begin to open some of the plugged openings in the patterned SiON layer, some of the openings remained plugged. Test 2, in which the process parameters were generally the same as those in Test 1, but where the etch time was increased from 30 seconds to 60 seconds, left some silicon-containing hard polymer residue on the SiON surface, but was nearly adequate to remove the residue.

An increase in the cathode temperature from −15° C. to 0° C. during the main etch, ME, step used to etch the α-carbon layer did reduce the hard polymer build up from what it had been under the standard ME etch conditions; however, the amount of silicon-containing hard polymer build-up (residue formation) during the ME was still unacceptable. The “Bar CD” obtained on the surface of the silicon oxynitride hard mask layer is still far in excess of the 70 nm of the patterned photoresist which was used to pattern the silicon oxynitride hard mask layer. The Bar CD at the center of the substrate after etch of the α-carbon layer had increased to 110 nm, while the Bar CD at the edge of the substrate had increased to 94 nm. This increase in the BAR CD is indicative of a decrease in the opening diameters at the upper surface of the α-carbon layer during the ME. In addition, the photomicrograph shows a significant amount of silicon-containing hard mask residue toward the upper surface opening of the α-carbon layer after the completion of the ME.

A decrease in the bias power applied to the substrate also helps reduce the silicon-containing hard polymer build up by reducing the amount of sputtering of the SiON mask during the α-carbon etch process. However, the shape of the well etched in the α-carbon layer becomes more bowed as the bias power is decreased, at least over a substrate biasing range where the Wb ranges from 300 W to 900 W. With this in mind, a selection of a mid range bias power of 600 W may be advisable.

A decision was made to try use of an intermittent cleaning step during the ME step, where the ME etch conditions would remain the same, but a cleaning etchant species would be added intermittently by the addition of at least one species producing plasma source gas during the cleaning, CL, step. In the first effort at using an intermittent CL step, the ME step was broken into four cycles, where each cycle included a 1 minute ME step followed by a 5 second CL step. The process conditions were as follows in Table Two.

TABLE TWO

| | H₂ | N₂ | O₂ | | | | Tc⁴ | Tw⁵ | He⁶ | |
|---|---|---|---|---|---|---|---|---|---|---|
| Step | sccm | sccm | sccm | Ws¹ | Wb² | Pr³ | ° C. | ° C. | Torr | Time⁷ |
| ME | 100 | 80 | 5 | 1600 | 600 | 15 | −15 | 15 | 12-12 | 1 min |
| CL | — | — | 50 | 1600 | 300 | 15 | −15 | 15 | 12-12 | 5 sec |

¹Plasma source power in Watts.
²Substrate bias power in Watts.
³Process chamber pressure in mTorr.
⁴Temperature of the substrate support platform.
⁵Temperature of the plasma chamber walls.
⁶Helium heat transfer back pressure was uniform at 12 Torr over the substrate surface.
⁷Etch time in seconds.
The plasma source gas flow control ratio was set so that the ratio inner:outer was 3:1 during the main etch step and during the CL step.

While the use of an O₂ cleaning step did help reduce the improve the profile control over the etched hole, there was still a hard polymer build up problem toward the surface opening in the amorphous carbon layer.

A decision was made to try use of an intermittent cleaning step in which the cleaning step would employ a source gas which provided fluorine species in combination with the source gas which provided oxygen species. Again, the ME etch conditions would remain the same, but additional gases would be added to the plasma source gas during the cleaning step. In the ME step with an intermittent CL step, the ME step was broken into four cycles, where each cycle included a 1 minute ME step followed by a 5 second CL step. The process conditions for a cycle were as follows in Table Three.

TABLE THREE

| | H₂ | N₂ | O₂ | CF₄ | | | | Tc⁴ | Tw⁵ | He⁶ | |
|---|---|---|---|---|---|---|---|---|---|---|---|
| Step | sccm | sccm | sccm | sccm | Ws¹ | Wb² | Pr³ | ° C. | ° C. | Torr | Time⁷ |
| ME | 120 | 60 | 5 | 0 | 1600 | 600 | 15 | −15 | 15 | 12-12 | 1 min |
| CL | 0 | 0 | 10 | 50 | 1600 | 300 | 15 | −15 | 15 | 12-12 | 5 sec |

¹Plasma source power in Watts.
²Substrate bias power in Watts.
³Process chamber pressure in mTorr.
⁴Temperature of the substrate support platform.
⁵Temperature of the plasma chamber walls.
⁶Helium heat transfer gas back pressure was uniform over the substrate surface at 12 Torr.
⁷Etch time in seconds.
The plasma source gas flow control ratio was set so that the ratio inner:outer was 3:1 during the ME and the CL step.

While the cleaning step did remove silicon-containing hard polymer residue, the patterned silicon oxynitride hard mask layer was eroded by the clean-up step, which was too strong. However, the increase in the ratio of H₂ to N₂ in the ME step did improve the etch profile of the well etched in the α-carbon layer and also improved the etch rate.

A series of experiments were carried out to improve etch uniformity and erosion rate over the substrate surface when a CL step was intermittently incorporated into the main etch, ME, of the α-carbon layer. Variable changes in process chamber pressure, plasma source power, substrate bias power, and oxygen flow rate were made. The length of the CL step was varied between about 4 sec/1 min ME to about 8 sec/1 min ME. After considerable experimentation we developed the process shown below in TABLE FOUR. This process provides excellent results.

TABLE FOUR

| | H₂ | N₂ | O₂ | CF₄ | | | | Tc⁴ | Tw⁵ | He⁶ | |
|---|---|---|---|---|---|---|---|---|---|---|---|
| Step | sccm | sccm | sccm | sccm | Ws¹ | Wb² | Pr³ | ° C. | ° C. | Torr | Time⁷ |
| ME | 120 | 60 | 5 | 0 | 1600 | 600 | 15 | −15 | 15 | 12-12 | 1 min |
| CL | 0 | 0 | 10 | 50 | 1600 | 100 | 15 | −15 | 15 | 12-12 | 4 sec |
| ME | 120 | 60 | 5 | 0 | 1600 | 600 | 15 | −15 | 15 | 12-12 | 1 min |
| CL | 0 | 0 | 10 | 50 | 1600 | 100 | 15 | −15 | 15 | 12-12 | 4 sec |
| ME | 120 | 60 | 5 | 0 | 1600 | 600 | 15 | −15 | 15 | 12-12 | 1 min |
| CL | 0 | 0 | 10 | 50 | 1600 | 100 | 15 | −15 | 15 | 12-12 | 4 sec |
| ME | 120 | 60 | 5 | 0 | 1600 | 600 | 15 | −15 | 15 | 12-12 | 38 sec |

¹Plasma source power in Watts.
²Substrate bias power in Watts.
³Process chamber pressure in mTorr.
⁴Temperature of the substrate support platform.
⁵Temperature of the plasma chamber walls.
⁶The helium heat transfer gas back pressure was uniform at 12 Torr over the surface of the substrate.
⁷Etch time in seconds.
The plasma source gas flow control ratio was set so that the ratio inner:outer was 3:1 during the ME step and the CL step.

While oxygen was used to provide oxygen cleaning species in the above examples, oxygen species may be provided using a plasma source gas selected from the group consisting of O₂, CO, CO₂, SO₂, and combinations thereof.

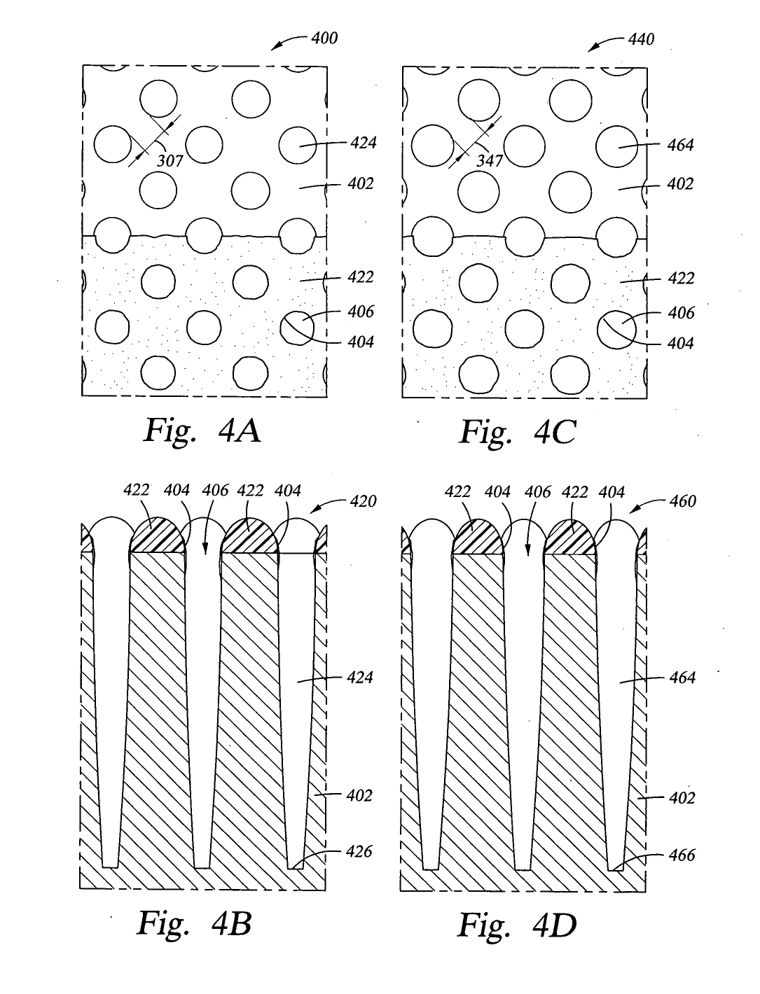

FIG. 4A shows a photomicrograph top view at the center of a semiconductor substrate where the holes in an α-carbon layer of the substrate were etched using the method of the invention. Use of the method has enabled etching of the holes with minimal effect on the etch profile due to hard polymer build up.

Photomicrograph 400 shows the center area top view of a substrate of the kind shown in FIG. 1, where the openings 406 in the pattern-etched α-carbon layer 402 are essentially free from the presence of silicon-containing hard polymer residue 404.

FIG. 4B shows a photomicrograph 420 side view of the etched α-carbon layer 402 shown in FIG. 4A. The α-carbon layer 402 has been etched to form wells 424, which have been etched to a depth of about 1700 nm, and the Critical Dimension diameter 426 at the base of a well 424 is approximately 84 nm. FIG. 4B also shows silicon oxynitride hard mask 422 which was not shown in FIG. 4A. The Critical Dimension diameter at the opening into the etched hole 424 in α-carbon layer 402 is approximately 99 nm, while the diameter 426 at the base of etched hole 424 is approximately 84 nm. A measurement of the photomicrograph indicates a bowing of about −0.64° on one side of the etched hole and about 1.12° on the other side of the hole. This shows that there is very minimal bowing of the hole 424.

FIG. 4C shows a photomicrograph 440 of a top view at the edge of the substrate shown in FIG. 4A, where the openings 406 in the pattern-etched α-carbon layer 402 are essentially free from the presence of silicon-containing hard polymer residue 404.

FIG. 4D shows a photomicrograph 460 side view of the of etched α-carbon layer 402 shown in FIG. 4C. The α-carbon layer 402 has been etched to form wells 464, which have been etched to a depth of about 1700 nm, and the Critical Dimension diameter 466 at the base of hole 464 is approximately 84 nm. The Critical Dimension diameter at the opening 406 into the etched hole 464 in α-carbon layer 402 is approximately 89 nm, while the diameter 466 at the base of etched hole 464 is approximately 84 nm. A measurement of the photomicrograph indicates a bowing of about −0.64° on one side of the etched hole and about 1.12° on the other side of the hole. Again, this shows that there is very minimal bowing of the hole 424.

The results achieved were better than the target values which were originally set at the beginning of experimentation. The wells etched in the α-carbon layer 108 shown in semiconductor structure 100 of FIG. 1 have been etched to a depth of about 1,700 nm, where the Critical Dimension diameter of the hole at the opening to the wells has a diameter of about 89 nm, an aspect ratio of nearly 20:1, with essentially no bowing, with a profile angle of about 89.2°, and the etch rate was over 5,500 Å/min (550 nm/min).

As previously mentioned, although the etch process chamber used to process the substrates described in the Examples presented herein was an inductively coupled etch chamber of the kind shown in schematic in FIG. 2, any of the etch processors available in the industry should be able to take advantage of the etch chemistry described herein, with some adjustment to other process parameters.

The above described exemplary embodiments are not intended to limit the scope of the present invention, as one skilled in the art can, in view of the present disclosure expand such embodiments to correspond with the subject matter of the invention claimed below.

We claim:

1. A method of plasma etching deeply recessed features having an aspect ratio of about 15:1 or greater to a depth of 1.5 μm or greater through a silicon-containing hard mask into a carbon-containing layer in a semiconductor substrate, said method comprising the intermittent use of a cleaning step within a continuous etching process, where at least one cleaning agent species is added to already present etchant species of said continuous etching process for a limited time period, wherein the length of time of each cleaning step ranges from about 5% to about 100% of the time length of an etch step which either precedes or follows said cleaning step during said continuous etching process, whereby a specific nominal depth of etching is obtained essentially without bowing of etched sidewalls of said deeply recessed features.

2. A method in accordance with claim 1, wherein the length of time of each cleaning step ranges from about 5% to about 10% of the time length of said etch step which either precedes or follows said cleaning step.

3. A method in accordance with claim 1, wherein said at least one cleaning etchant species is selected from the group consisting of a fluorine-containing species, an oxygen-containing species, or a combination thereof.

4. A method in accordance with claim 3, wherein said fluorine-containing etchant species are generated from a plasma source gas selected from the group consisting of SF₆, NF₃, CₓF_{y}, and combinations thereof.

5. A method in accordance with claim 4, wherein said fluorine-containing species are generated from CₓF_{y}, wherein the ratio of x: y ranges from about 1:4 to about 1:1.

6. A method in accordance with claim 3 or claim 4, or claim 5, wherein said oxygen-containing species are generated from a plasma source gas selected from the group consisting of O₂, CO, CO₂, SO₂, and combinations thereof.

7. A method in accordance with claim 6, wherein said oxygen-containing species is generated from O₂.

8. A method in accordance with claim 1 or claim 2, or claim 3, or claim 4, or claim 5, wherein said carbon-containing layer is α-carbon.

9. A method in accordance with claim 6, wherein said carbon-containing layer is α-carbon.

10. A method in accordance with claim 7, wherein said carbon-containing substrate is α-carbon.

11. A method in accordance with claim 8, wherein said continuous etching process average etch rate is at least 500 nm/min.

12. A method in accordance with claim 9, wherein said continuous etching process average etch rate is at least 500 nm/min.

13. A method in accordance with claim 10, wherein said continuous etching process average etch rate is at least 500 nm/min.

14. A method in accordance with claim 1, or claim 2, or claim 3, or claim 4, or claim 5, wherein reactive etchant species used during said continuous etching process are selected from the group consisting of H₂, N₂, O₂ and combinations thereof.

15. A method in accordance with claim 8, wherein reactive etchant species used during said continuous etching process are selected from the group consisting of H₂, N₂, O₂ and combinations thereof.

16. A method in accordance with claim 9, wherein reactive etchant species used during said continuous etching process are selected from the group consisting of H₂, N₂, O₂ and combinations thereof.

17. A method in accordance with claim 10, wherein reactive etchant species used during said continuous etching process are selected from the group consisting of H₂, N₂, O₂ and combinations thereof.

18. A method in accordance with claim 4, wherein non-reactive species selected from the group consisting of helium, argon, neon, xenon, and combinations thereof are present in a plasma used during said continuous etching process.

19. A method in accordance with claim 14, wherein non-reactive species selected from the group consisting of helium, argon, neon, xenon, and combinations thereof are present in a plasma used during said continuous etching process.

20. A method in accordance with claim 17, wherein non-reactive helium species are present in a plasma used during said continuous etching process.

21. A method in accordance with claim 18, wherein non-reactive helium species are present in a plasma used during said continuous etching process.

22. A method of removing a silicon-containing and carbon-containing hard polymeric material from an opening leading to a recessed feature during the plasma etching of said feature into a carbon-containing substrate, wherein method comprises the intermittent use of a cleaning step within a continuous etching process, where at least one fluorine-containing cleaning agent species is added to already present etchant species of said continuous etching process for a limited time period, wherein the length of time of each cleaning step ranges from about 5% to about 100% of the time length of an etch step which either precedes or follows said cleaning step during said continuous etching process.

23. A method in accordance with claim 22, wherein the length of time of each cleaning step ranges from about 5% to about 10% of the time length of said etch step which either precedes or follows said cleaning step.

24. A method in accordance with claim 22, wherein an oxygen-containing cleaning agent species is added to said fluorine-containing cleaning agent species during said intermittent cleaning step.

25. A method in accordance with claim 23 or claim 24, wherein said fluorine-containing etchant species are generated from a plasma source gas selected from the group consisting of SF₆, NF₃, CₓF_{y}, and combinations thereof.

26. A method in accordance with claim 24, wherein said fluorine-containing species are generated from CₓF_{y}, wherein the ratio of x: y ranges from about 1:4 to about 1:1.

27. A method in accordance with claim 26, wherein said fluorine-containing species are generated from CF₄.

28. A method in accordance with claim 27, wherein said oxygen-containing species are generated from a plasma source gas selected from the group consisting of O₂, CO, CO₂, SO₂, and combinations thereof.

29. A method in accordance with claim 28, wherein said oxygen-containing species is generated from O₂.

30. A method in accordance with claim 23 or claim 24, wherein said carbon-containing substrate is α-carbon.

31. A method in accordance with claim 25, wherein said carbon-containing substrate is α-carbon.

32. A method in accordance with claim 26, wherein said carbon-containing substrate is α-carbon.

33. A method in accordance with claim 30, wherein said continuous etching process average etch rate is at least 500 nm/min.

34. A method in accordance with claim 31, wherein said continuous etching process average etch rate is at least 500 nm/min.

35. A method in accordance with claim 32, wherein said continuous etching process average etch rate is at least 500 nm/min.

36. A method in accordance with claim 23, or claim 24, wherein reactive etchant species used continuously during said continuous etching process are selected from the group consisting of H₂, N₂, O₂ and combinations thereof.

37. A method in accordance with claim 25, wherein reactive etchant species used continuously during said continuous etching process are selected from the group consisting of H₂, N₂, O₂ and combinations thereof.

38. A method in accordance with claim 29, wherein reactive etchant species used during said continuous etching process are selected from the group consisting of H₂, N₂, O₂ and combinations thereof.

39. A method in accordance with claim 30, wherein reactive etchant species used continuously during said continuous etching process are selected from the group consisting of H₂, N₂, O₂ and combinations thereof.

40. A method in accordance with claim 23, wherein non-reactive species selected from the group consisting of helium, argon, neon, xenon, and combinations thereof are present in a plasma used during said continuous etching process.

41. A method in accordance with claim 24, wherein non-reactive species selected from the group consisting of helium, argon, neon, xenon, and combinations thereof are present in a plasma used during said continuous etching process.

42. A method in accordance with claim 25, wherein non-reactive species selected from the group consisting of helium, argon, neon, xenon, and combinations thereof are present in a plasma used during said continuous etching process.

43. A method in accordance with claim 36, wherein non-reactive species selected from the group consisting of helium, argon, neon, xenon, and combinations thereof are present in a plasma used during said continuous etching process.
